(19) United States
(12) Patent Application Publication
(10) Pub. No.: US 2023/0077959 A1
(43) Pub. Date: Mar. 16, 2023

(54) IGBT DEVICE BACKSIDE STRUCTURE AND PREPARATION METHOD THEREFOR, AND IGBT DEVICE

(71) Applicants: STATE GRID SMART GRID RESEARCH INSTITUTE CO., LTD., Beijing (CN); STATE GRID SHANXI ELECTRIC POWER RESEARCH INSTITUTE, Taiyuan, Shanxi (CN); STATE GRID CORPORATION OF CHINA, Beijing (CN)

(72) Inventors: Li LI, Beijing (CN); Rui JIN, Beijing (CN); Yaohua WANG, Beijing (CN); Shaohua DONG, Beijing (CN); Jiang LIU, Beijing (CN); Mingchao GAO, Beijing (CN); Junmin WU, Beijing (CN); Lu BAI, Beijing (CN); Guanliang LI, Beijing (CN)

(73) Assignees: STATE GRID SMART GRID RESEARCH INSTITUTE CO., LTD., Beijing (CN); STATE GRID SHANXI ELECTRIC POWER RESEARCH INSTITUTE, Taiyuan, Shanxi (CN); STATE GRID CORPORATION OF CHINA, Beijing (CN)

(21) Appl. No.: 17/759,411

(22) PCT Filed: Jun. 15, 2021
(86) PCT No.: PCT/CN2021/100045

§ 371 Date: Jul. 25, 2022

(30) Foreign Application Priority Data
Jun. 24, 2020 (CN) 202010594130.8

(51) Int. Cl. H01L 29/08; H01L 29/06; H01L 29/739; H01L 21/265; H01L 21/268; H01L 29/66

(52) U.S. Cl. CPC H01L 29/0834; H01L 29/0638; H01L 29/7395; H01L 21/26513; H01L 21/268; H01L 29/66333

(57) ABSTRACT

Provided in the present disclosure are an IGBT device backside structure and a preparation method therefor, and an IGBT device, the IGBT device backside structure comprising a buffer layer, the buffer layer comprising a first activation efficiency buffer area corresponding to an active area of the IGBT device and a second activation efficiency buffer area corresponding to a terminal area of the IGBT device, the activation efficiency of the first activation efficiency buffer area being less than the activation efficiency of the second activation efficiency buffer area.

### CROSS-REFERENCE TO RELATED APPLICATIONS

This application is based on and claims priority to Chinese Patent Application No. 202010594130.8 filed on Jun. 24, 2020 and entitled “IGBT DEVICE BACKSIDE STRUCTURE AND PREPARATION METHOD THEREFOR, AND IGBT DEVICE”, the entire contents of which are incorporated herein by reference.

### TECHNICAL FIELD

The disclosure relates to the technical field of semiconductor devices, and in particular to a backside structure of an Insulated Gate Bipolar Transistor (IGBT) device, a method of preparing the backside structure, and an IGBT device.

### BACKGROUND

At present, an IGBT, also known as an Insulated Gate Bipolar Transistor, is the most representative power electronic device. The IGBT is a composite full-control-type voltage-driven-type power semiconductor device composed of a Bipolar Junction Transistor (BJT) and a Metal Oxide Semiconductor Field Effect Transistor (MOS), and has a characteristic of self-turn-off, so that it has advantages of both a BJT device and an MOS device, such as voltage-controlled switching, high operating frequency, simple drive-controlling circuit, bipolar conduction, or the like. Since the birth of IGBT technology, the IGBT technology has developed for more than 30 years, and the IGBT technology has undergone four generations of changes, which are known as a first generation of planar gate punch-through type, a second generation of planar gate non-punch-through type, a third generation of trench gate field cut-off type, and a fourth generation of carrier storage trench gate bipolar transistor, sequentially.

An IGBT device has a characteristic of self-turn-off, may be regarded as a lead when it is turned on, and may be regarded as an open circuit when it is turned off. In a practical application of a power system, it is necessary to ensure the IGBT device to be safely turned off under a relatively severe condition and to bear a fault current for a long time, and thus higher requirements are provided for turn-off capability of the IGBT device. Therefore, it is necessary for the IGBT device applied in the field of the power system to have a strong overcurrent turn-off capability while satisfying basic static and dynamic characteristics and reliability.

A traditional IGBT device includes a drift region, an active region disposed above the drift region, and two terminal regions disposed at two ends of the active region respectively, and further includes a buffer layer, a backside P+ region and a collector metal layer which are disposed on a side, far away from the active region, of the drift region. The buffer layer, the backside P+ region and the collector metal layer form a backside structure of the IGBT device, the buffer layer may be activated in a thermal annealing mode or in a laser annealing mode, an activation efficiency of the buffer layer obtained through thermal annealing is about 100%, and an activation efficiency of the buffer layer obtained through laser annealing is over 85%. When the device is turned off, holes, injected from the backside P+ region, of the terminal regions need to be collected through a main junction at an edge of the active region, and current concentration phenomenon of hole current may be occurred at the main junction, which easily causes turn-off failure.

### SUMMARY

Therefore, the technical problem to be solved by the disclosure is to overcome a defect of current concentration occurring at the main junction at the edge of the active region when an existing IGBT device is turned off, which easily causes turn-off failure, therefore the disclosure provides a backside structure of an IGBT device, a method for preparing the backside structure, and an IGBT device.

According to a first aspect of embodiments of the disclosure, there is provided a backside structure of an IGBT device, including a buffer layer which includes a first activation efficiency buffer corresponding to an active region of the IGBT device and a second activation efficiency buffer corresponding to a terminal region of the IGBT device, here an activation efficiency of the first activation efficiency buffer is smaller than an activation efficiency of the second activation efficiency buffer.

In some embodiments, the activation efficiency of the first activation efficiency buffer may range from 15% to 25%, and the activation efficiency of the second activation efficiency buffer may range from 85% to 95%.

In some embodiments, the buffer layer may have doping elements including phosphorus, and have a junction depth ranging from 2 micrometer (pm) to 3 μm.

In some embodiments, a side, far away from a drift region of the IGBT device, of the buffer layer may further be provided with a backside P+ region and a collector metal layer, and the buffer layer, the backside P+ region and the collector metal layer are stacked.

In some embodiments, the backside P+ region may have doping elements including boron, and have a thickness ranging from 0.4 μm to 0.6 μm.

According to a second aspect of the embodiments of the disclosure, there is provided an IGBT device, adopting the backside structure of the IGBT device as described above.

According to a third aspect of the embodiments of the disclosure, there is provided a method for preparing a backside structure of an IGBT device, including the following operations.

Preparation of a front structure of the IGBT device is performed on a front side of a wafer, and then first ion implantation is performed on a back side of the wafer, to form a buffer layer; here the front side of the wafer and the back side of the wafer are opposite surfaces of the wafer.

First laser annealing is performed on the buffer layer, so that a region, corresponding to an active region of the IGBT device, of the buffer layer forms a first activation efficiency buffer, and a region, corresponding to a terminal region of the IGBT device, of the buffer layer forms a second activation efficiency buffer; here an activation efficiency of the first activation efficiency buffer is smaller than an activation efficiency of the second activation efficiency buffer.

In some embodiments, conditions of forming the first activation efficiency buffer may include: the laser has a wavelength ranging from 510 nanometer (nm) to 550 nm, and has energy ranging from 1.5 J/cm² to 2.5 J/cm²;

conditions of forming the second activation efficiency buffer may include: the laser has a wavelength ranging from 510 nm to 550 nm, and has energy ranging from 5 J/cm² to 6 J/cm².

In some embodiments, the method for preparing the backside structure of the

IGBT device may further include the following operations.

Second ion implantation is performed on the back side of the wafer, to form a backside P+ layer on a side, far away from a drift region of the IGBT device, of the buffer layer, and second laser annealing is performed on the backside P+ layer.

A backside metal electrode is formed on a side, far away from the buffer layer, of the backside P+ layer.

In some embodiments, the first ion implantation may have a dose ranging from 5E13 cm⁻² to 1E14 cm⁻², and apply elements including phosphorous;

the second ion implantation may have a dose ranging from 1E14 cm⁻² to 5E14 cm⁻², and apply elements including boron.

In some embodiments, the performing second laser annealing on the backside P+ layer may include the following operations.

The second laser annealing is performed on elements located in the backside P+ layer and located within a preset distance from the side, far away from the buffer layer, of the backside P+ layer; here the preset distance ranges from 0.4 μm to 0.6 μm.

Technical solutions of the disclosure have the following advantages.

1. According to the backside structure of the IGBT device and the IGBT device provided by the disclosure, the buffer layer includes the first activation efficiency buffer corresponding to the active region of the IGBT device and the second activation efficiency buffer corresponding to the terminal region of the IGBT device, here an activation efficiency of the first activation efficiency buffer is smaller than an activation efficiency of the second activation efficiency buffer.

An effective doping concentration (N_{DSPT}) is inversely proportional to a current gain (β_{PNP}) of a Parasitic Transistor (PNP) of the IGBT device, and a hole implantation efficiency of the terminal region increases along with the increase of the current gain (β_{PNP}), that is, the hole implantation efficiency is gradually reduced along with the increase of the effective doping concentration (N_{DSPT}). The region, corresponding to the active region, of the buffer layer is disposed as the first activation efficiency buffer, the region, corresponding to the terminal region, of the buffer layer is disposed as the second activation efficiency buffer, meanwhile, the activation efficiency of the second activation efficiency buffer is greater than that of the first activation efficiency buffer, so that the effective doping concentration (N_{DSPT}) of the terminal region is increased, and the hole implantation efficiency of the terminal region is reduced. When an IGBT device chip is turned off due to overcurrent, holes injected into the terminal region are collected through a main junction when the IGBT is turned off, so that current concentration phenomenon at the main junction of an edge of the active region is reduced, and overcurrent turn-off performance of the device is improved.

2. The IGBT device provided by the disclosure has higher breakdown voltage and smaller leakage current, and thus has more excellent breakdown characteristic.

3. According to the method for preparing the backside structure of the IGBT device provided by the disclosure, the buffer layer may be prepared only by performing first laser annealing after first ion implantation, the method is compatible with a traditional process of manufacturing an IGBT, meanwhile, the method does not require an additional lithography process, and has a simple preparation process.

### BRIEF DESCRIPTION OF THE DRAWINGS

In order to describe specific implementations of the disclosure or technical solutions in the related art more clearly, the drawings required to be used in descriptions of the specific implementations or the related art will be simply introduced below, and it is apparent that the drawings as described below are only some implementations of the disclosure, and other drawings may further be obtained by those of ordinary skill in the art according to the drawings without paying any creative work.

FIG. 1 is a schematic structural diagram of an IGBT device provided by a first embodiment of the disclosure.

FIG. 2 is a schematic structural diagram of an IGBT device provided by a first comparative example of the disclosure.

FIG. 3 is a relationship curve of comparison of breakdown voltages of an

IGBT device provided by an embodiment of the disclosure and an IGBT device provided by the first comparative example.

### DESCRIPTION OF REFERENCE NUMERALS

1. Drift region; 2. Active region; 3. Terminal region; 4. Buffer layer; 41. First activation efficiency buffer; 42. Second activation efficiency buffer; 5. Backside P+region; and 6. Collector metal layer.

### DETAILED DESCRIPTION

The following embodiments are provided to better understand the disclosure, and are not limited to the described optimal implementations, and do not limit the contents and the scope of protection of the disclosure. Any product identical or similar to the disclosure, which may be obtained by anyone in the inspiration of the disclosure or by combining the disclosure with other features of the related art, falls within the scope of protection of the disclosure.

In the descriptions of the disclosure, it should be noted that orientation or position relationships indicated by terms “upper”, “lower”, “interior”, “exterior”, or the like are based on orientation or position relationships shown in the drawings, are only used to facilitate descriptions of the disclosure and simplify descriptions, rather than indicating or implying that indicated devices or components must be arranged in specific orientations or configured and operated in specific orientations, and thus should not be understood as limitations of the disclosure. In addition, terms “first” and “second” are only used for descriptions and should not be understood as indicating or implying relative importance.

### First Embodiment

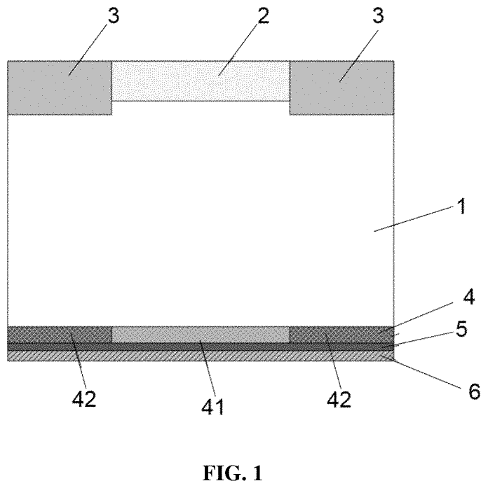

As shown in FIG. 1, the embodiment provides a backside structure of an IGBT device, including a buffer layer 4 which includes a first activation efficiency buffer 41 corresponding to an active region 2 of the IGBT device and a second activation efficiency buffer 42 corresponding to a terminal region 3 of the IGBT device, here an activation efficiency of the first activation efficiency buffer 41 is smaller than an activation efficiency of the second activation efficiency buffer 42.

An effective doping concentration (N_{DSPT}) is inversely proportional to a current gain (β_{PNP}) of a Parasitic Transistor (PNP) of the IGBT device, therefore a hole implantation efficiency of the terminal region 3 of the IGBT device increases along with the increase of the current gain (β_{PNP}), that is, the hole implantation efficiency is gradually reduced along with the increase of the effective doping concentration (N_{DSPT}). The region, corresponding to the active region 2, of the buffer layer 4 is disposed as the first activation efficiency buffer 41, the region, corresponding to the terminal region 3, of the buffer layer 4 is disposed as the second activation efficiency buffer 42, and the activation efficiency of the second activation efficiency buffer 42 is greater than that of the first activation efficiency buffer 41, so that the effective doping concentration (N_{DSPT}) of the terminal region 3 is increased, and the hole implantation efficiency of the terminal region 3 is reduced. When an IGBT device chip is turned off due to overcurrent, holes injected into the terminal region 3 are collected through a main junction when the IGBT is turned off, so that current concentration phenomenon at the main junction of an edge of the active region 2 is reduced, and overcurrent turn-off performance of the device is improved. Furthermore, the IGBT device has higher breakdown voltage and smaller leakage current, and thus has more excellent breakdown characteristic.

Specifically, the buffer layer 4 may have doping elements including phosphorus, and have a junction depth ranging from 2 μm to 3 μm, here the activation efficiency of the first activation efficiency buffer 41 may range from 15% to 25%, and the activation efficiency of the second activation efficiency buffer 42 may range from 85% to 95%.

In some embodiments, a side, far away from a drift region 1 of the IGBT device, of the buffer layer 4 may further be provided with a backside P+ region 5 and a collector metal layer 6, and the buffer layer 4, the backside P+ region 5 and the collector metal layer 6 are stacked. Specifically, the backside P+ region 5 may have doping elements including boron, and have a thickness ranging from 0.4 μm to 0.6 μm.

The embodiment further provides an IGBT device, adopting the backside structure of the IGBT device as described above. A front structure of the IGBT device includes an active region 2 and a terminal region 3 disposed outside of the active region, and the terminal region 3 is flushed with the active region 2. The IGBT device has all the advantages of the backside structure as described above, which are not elaborated here.

### Second Embodiment

The embodiment provides a method for preparing a backside structure of an IGBT device, which may obtain the IGBT device provided by the first embodiment and specifically includes the following operations.

(1) Preparation of a front structure of the IGBT device is performed on a front side of a wafer, and then first ion implantation is performed on a back side of the wafer, to form a buffer layer; here the front side of the wafer and the back side of the wafer are opposite surfaces of the wafer.

(2) First laser annealing is performed on the buffer layer, here a region, corresponding to an active region of the IGBT device, of the buffer layer forms a first activation efficiency buffer, and a region, corresponding to a terminal region of the IGBT device, of the buffer layer forms a second activation efficiency buffer.

Specifically, the first ion implantation may have a dose ranging from 5E13 cm⁻² to 1E14 cm⁻², and apply elements including phosphorous. Conditions of forming the first activation efficiency buffer may include: the laser has a wavelength ranging from 510 nm to 550 nm, and has energy ranging from 1.5 J/cm² to 2.5 J/cm²; conditions of forming the second activation efficiency buffer may include: the laser has a wavelength ranging from 510 nm to 550 nm, and has energy ranging from 5 J/cm² to 6 J/cm².

(3) Second ion implantation is performed on the back side of the wafer, to form a backside P+ layer on a side, far away from a drift region of the IGBT device, of the buffer layer, and second laser annealing is performed on the backside P+ layer. Specifically, the second ion implantation may have a dose ranging from 1E14 cm ⁻² to 5E14 cm⁻², and apply elements including boron.

(4) A backside metal electrode is formed on a side, far away from the buffer layer, of the backside P+ layer.

### FIRST COMPARATIVE EXAMPLE

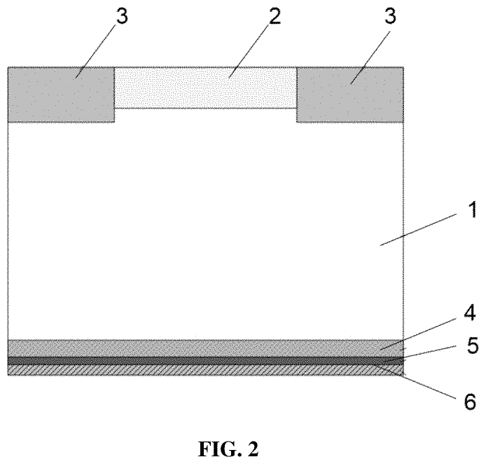

As shown in FIG. 2, the comparative example provides an IGBT device, which differs from the first embodiment only in that a buffer layer in a backside structure thereof has an activation efficiency of is 90%.

### EXPERIMENTAL EXAMPLE

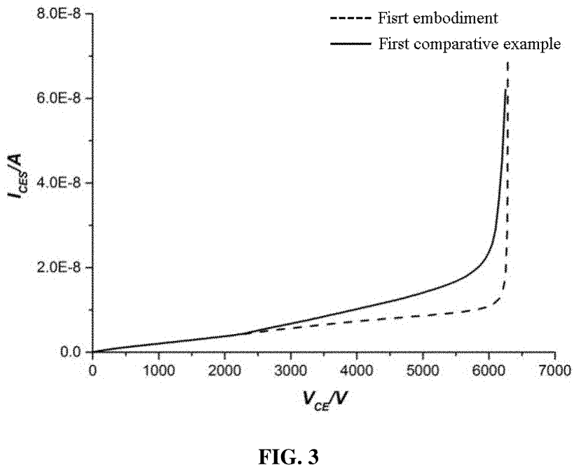

A relationship curve of comparison of breakdown voltages of the IGBT device provided by the embodiment and the IGBT device provided by the comparative example may be obtained by performing a breakdown voltage test on collector-emitter of the IGBT (test conditions are as follows: Vge=0V, and a voltage applied between the collector and the emitter is gradually increased, from 0V to a breakdown point). As shown in FIG. 3, a horizontal axis V_{CE} represents a voltage of a collector-emitter of the IGBT device chip, and a vertical axis I_{CES} represents a leakage current of the collector-emitter of the IGBT device chip.

As may be known from FIG. 3, the IGBT device provided by the embodiment has a higher breakdown voltage, a smaller leakage current and more excellent breakdown characteristic.

It is apparent that the above embodiments are merely examples made for clarity of illustration and are not limitations of the embodiments. Other different changes or variations may also be made by those of ordinary skill in the art based on the above descriptions. It is not necessary and impossible to exhaustively provide all the implementations here. Furthermore, apparent changes or variations therefrom still fall within the scope of protection of the disclosure.

1. A backside structure of an Insulated Gate Bipolar Transistor (IGBT) device, comprising a buffer layer which comprises a first activation efficiency buffer corresponding to an active region of the IGBT device and a second activation efficiency buffer corresponding to a terminal region of the IGBT device, wherein an activation efficiency of the first activation efficiency buffer is smaller than an activation efficiency of the second activation efficiency buffer.

2. The backside structure of the IGBT device of claim 1, wherein the activation efficiency of the first activation efficiency buffer ranges from 15% to 25%, and the activation efficiency of the second activation efficiency buffer ranges from 85% to 95%.

3. The backside structure of the IGBT device of claim 1, wherein the buffer layer has doping elements comprising phosphorus, and has a junction depth ranging from 2 micrometer (μm) to 3 μm.

4. The backside structure of the IGBT device of claim 3, wherein a side, far away from a drift region of the IGBT device, of the buffer layer is further provided with a backside P+region and a collector metal layer, and the buffer layer, the backside P+ region and the collector metal layer are stacked.

5. The backside structure of the IGBT device of claim 4, wherein the backside P+ region has doping elements comprising boron, and has a thickness ranging from 0.4 μm to 0.6 μm.

6. An Insulated Gate Bipolar Transistor (IGBT) device, comprising the backside structure of the IGBT device of claim 1.

7. A method for preparing a backside structure of an Insulated Gate Bipolar Transistor (IGBT) device, comprising the following steps:
performing preparation of a front structure of the IGBT device on a front side of a wafer, and then performing first ion implantation on a back side of the wafer, to form a buffer layer; wherein the front side of the wafer and the back side of the wafer are opposite surfaces of the wafer; and
performing first laser annealing on the buffer layer, so that a region, corresponding to an active region of the IGBT device, of the buffer layer forms a first activation efficiency buffer, and a region, corresponding to a terminal region of the IGBT device, of the buffer layer forms a second activation efficiency buffer; wherein an activation efficiency of the first activation efficiency buffer is smaller than an activation efficiency of the second activation efficiency buffer.

8. The method for preparing the backside structure of the IGBT device of claim 7, wherein conditions of forming the first activation efficiency buffer comprise: the laser has a wavelength ranging from 510 nanometer (nm) to 550 nm, and has energy ranging from 1.5 J/cm² to 2.5 J/cm²;
conditions of forming the second activation efficiency buffer comprises: the laser has a wavelength ranging from 510 nm to 550 nm, and has energy ranging from 5 J/cm² to 6 J/cm².

9. The method for preparing the backside structure of the IGBT device of claim 7, further comprising the following steps:
performing second ion implantation on the back side of the wafer, to form a backside P+ layer on a side, far away from a drift region of the IGBT device, of the buffer layer, and performing second laser annealing on the backside P+ layer; and
forming a backside metal electrode on a side, far away from the buffer layer, of the backside P+ layer.

10. The method for preparing the backside structure of the IGBT device of claim 9, wherein the first ion implantation has a dose ranging from 5E13 cm⁻² to 1E14 cm ², and applies elements comprising phosphorous;
the second ion implantation has a dose ranging from 1E14 cm⁻² to 5E14 cm⁻², and applies elements comprising boron.

11. The method for preparing the backside structure of the IGBT device of claim 9, wherein the performing second laser annealing on the backside P+ layer comprises:
performing the second laser annealing on elements located in the backside P+ layer and located within a preset distance from the side, far away from the buffer layer, of the backside P+ layer; wherein the preset distance ranges from 0.4 micrometer (μm) to 0.6 μm.
